(19) United States
(12) Patent Application Publication
(10) Pub. No.: US 2024/0113563 A1
(43) Pub. Date: Apr. 4, 2024

(54) WIRELESS POWER TRANSFER DEVICE

(71) Applicant: AUCKLAND UNISERVICES LIMITED, Auckland (NZ)

(72) Inventors: Aiguo HU, Auckland (NZ); Liang HUANG, Auckland (NZ); Wei ZHOU, Chongqing (CN)

(21) Appl. No.: 18/533,475

(22) Filed: Dec. 8, 2023

Related U.S. Application Data
(63) Continuation of application No. 16/977,549, filed on Sep. 2, 2020, now Pat. No. 11,843,245.

(30) Foreign Application Priority Data
Mar. 2, 2018 (NZ) 740328

(51) Int. Cl. H02J 50/12; H01F 38/14; H02J 50/05

(52) U.S. Cl. CPC H02J 50/12; H01F 38/14; H02J 50/05

(57) ABSTRACT

A wireless power transfer apparatus for capacitive-inductive power transfer has a primary and a secondary device separated by the conductive member. The primary device has at least two transmitter plates configured to be capacitively coupled with the conductive member to induce a current flow and generate a magnetic field in the conductive member. The secondary device is connectable to a load and provided with a receiving coil configured to be inductively coupled with the conductive member.

### FIELD OF THE INVENTION

The present invention relates to wireless power transfer systems and has particular, but not sole, relevance to systems using inductive or capacitive (wireless) power transfer topologies.

In particular, though not solely, the present invention aims at providing an improved circuit topology that enables the use of combined capacitive and inductive coupling to wirelessly transfer power across a conductive surface. Additionally, this approach also reduces the impact of eddy currents and losses in the system, thereby reducing system size and cost, and improving energy density and reliability.

### BACKGROUND OF THE INVENTION

Wireless power transfer (WPT) was originally proposed by Tesla in 1891 to transfer power without direct electrical connections using near-field electromagnetic induction. With the development of power electronics, WPT techniques have been extensively researched and applied in many fields like electrical motors, consumer electronics, medical implant, and transportation systems owing to its advantages in flexibility, convenience, and safety.

Inductive power transfer (IPT) and capacitive power transfer (CPT) are two most popular WPT technologies based on magnetic field coupling and electric field coupling, respectively. Most WPT systems have non-conductive power transfer channels like air and insulated materials. But in many practical applications, it is common to have metal barriers between the primary power supply and secondary electric loads, such as for charging mobile electronic devices with metal back covers, powering fish finders across metallic boat hulls, and transferring power into metallic containers. In these applications power is normally transferred by direct connections, or even by drilling holes to allow drive cables to go through the metal barriers. However, such solutions may cause watertightness, structural, and maintenance issues, so it would desirable to achieve wireless power transfer in these applications.

Notwithstanding, existing WPT power supplies are not suitable for transferring power across conductive barriers. IPT systems involves large eddy current inside metal barriers which can cause high losses and safety concerns, and the metal barrier can shield the power flow. Similarly, for typical CPT systems with two pair of coupling plates, some of the literatures claim that CPT systems can transfer power across metal barriers. Actually, conventional CPT systems can only transfer power through metal barriers as long as the coupling electric field is not fully shielded. When both transmitting plates are fully covered by the metal barrier, conventional CPT systems cannot transfer power across the metal barrier because the electric field density near the receiving plates is almost the same and the power is blocked.

Researchers in this area have tried to improve IPT systems by reducing the eddy current effect in metal barriers. Some previous implementations in this field include:
i. a bulky inductive power transfer system with a low operating frequency of 50 Hz for supplying power to electrical sensors or devices working in a space covered by metal walls; results of this implementation showed that 3 W of electric power can be supplied to LEDs through a stainless steel wall 1 mm thick,
ii. the feasibility of power transfer through a steel pipe using two coupled coils; results of this implementation indicated that a maximum open circuit electromagnetic force (EMF) of 10V is achieved at frequency of 100 Hz, but the final power transfer capacity is not given, and
iii. an IPT system transferring power through a stainless steel disc with a thickness of mm and diameter of 130 mm; results indicated that an output power of several milliwatts is achieved at an operating frequency of 500 Hz for the sensor applications.

However, the limitations of the above methods can be mainly attributed to the low operating frequencies. Furthermore, all these IPT systems run at very low operating frequencies from 50 Hz to 500 Hz levels to reduce the eddy current losses. Increasing the operating frequencies of these systems can be an expensive solution. Due to the low frequency operation, the size of transmitting coil has to be relatively large so as to generate sufficient EMFs on the pickup coils, otherwise the output power would be very low.

The present invention is directed to overcoming one or more of the problems set forth above by providing an improved circuit topology to address some of the drawbacks found in previously developed IPT systems.

In this specification where reference has been made to patent specifications, other external documents, or other sources of information, this is generally for the purpose of providing a context for discussing the features of the invention. Unless specifically stated otherwise, reference to such external documents is not to be construed as an admission that such documents, or such sources of information, in any jurisdiction, are prior art, or form part of the common general knowledge in the art.

### OBJECTS OF THE INVENTION

It is an object of the invention to provide an apparatus, method or system which will at least go some way to overcoming disadvantages of existing systems, or which will at least provide a useful alternative to existing systems.

Further objects of the invention will become apparent from the following description.

### SUMMARY OF INVENTION

Accordingly, in one aspect the invention may broadly consist in a wireless power transfer apparatus for wirelessly transferring power across an electrically conductive member, the apparatus comprising:
a primary device and a secondary device separated by the conductive member; the primary device connectable to a power source, the primary device having at least two transmitter plates configured to be capacitively coupled with the conductive member to induce a current flow and generate a magnetic field in the conductive member; and
the secondary device connectable to a load and provided with a receiving coil configured to be inductively coupled with the conductive member.

Preferably, a frequency of the power source is chosen such that a magnetic flux density near edges of the conductive member is higher than that in middle region of the conductive member.

Preferably, the two transmitter plates are located across distal ends of the conductive member and form capacitors in series arrangement with the conductive member.

Preferably, the primary device further comprises a primary compensation circuit to counteract a reactance of the transmitters and reduce the higher-order harmonics in the transmitters.

Preferably, the primary compensation circuit includes a compensating inductor or an inductor or a capacitor.

Preferably, the secondary device further comprises a secondary compensation circuit connected to the receiving coil and the load.

Preferably, the secondary compensation circuit is at or near resonance with the receiving coil.

Preferably, the primary device further comprises in a control means to adjust an operating frequency of the wireless power transfer apparatus.

Preferably, the control means to adjust the operating frequency includes a rectifier and a subsequent inverter.

Preferably, the control means to adjust the operating frequency further includes a AC-AC converter.

Preferably, the receiving coil comprises a reflection coil positioned at a side of the receiving coil opposite the conductor member.

Preferably, the reflection coil further comprise a ferrite and/or a non-ferrite reflection material.

Preferably, the receiving coil is positioned relative to the conductive member such that the eddy currents in the conductive member are lower than a threshold.

Preferably, the primary device is connected directly to the conductive member.

Preferably, the conductive member comprises a conductive layer or a conductive surface.

In another aspect the invention may be said to broadly consist in a primary device for wirelessly transferring power across an electrically conductive member, the primary device connectable to a power source and comprising:
at least two transmitter plates configured to be capacitively coupled with the conductive member to induce a current flow and generate a magnetic field in the conductive member.

Preferably, the primary device is separable via the conducting member to a secondary device connected to a load and provided with a receiving coil and the secondary device being inductively coupled with the conductive member.

In another aspect the invention may be said to broadly consist in a secondary device for wirelessly transferring power across an electrically conductive member, the secondary device connectable to a load and comprising:
a receiving coil configured to be inductively coupled with the conductive member.

Preferably, the secondary device is separable via the conductive member to a primary device having at least two transmitter plates capacitively coupled with the conductive member to induce a current flow and generate a magnetic field in the conductive member.

Preferably, the secondary device further comprises the electrically conductive member and the receiving coil.

In another aspect the invention may be said to broadly consist in a method for wirelessly transferring power across an electrically conductive member, the method comprising:
providing a primary device connectable to a power source and having at least two transmitter plates configured to be capacitively coupled with the conductive member to induce a current flow and generate a magnetic field in the conductive member;
providing a secondary device connectable to a load and having with a receiving coil configured to be inductively coupled with the conductive member; and wherein the primary and secondary devices are separated by the conductive member.

In another aspect the invention may be said to broadly consist in a power transfer apparatus for transferring power across an electrically conductive member, the apparatus being operable in a first and a second connection mode, the apparatus comprising:
a primary device connectable to a power source and having at least two transmitter plates configured to be selectively capacitively coupled with the conductive member and to induce a current flow and generate a magnetic field therein;
a switching means to switch between the first and second connection modes; wherein in the first connection mode, the primary device is connected to the at least two transmitter plates and in the second connection mode the primary device is directly connected to the conductive member.

In another aspect the invention may be said to broadly consist in a power transfer apparatus for transferring power across an electrically conductive member, the apparatus being operable in a first and a second connection mode, the apparatus comprising:
power transfer apparatus for transferring power across an electrically conductive member, the apparatus being operable in a first and a second connection mode, the apparatus comprising:
a secondary device connectable to a load and provided with a receiving coil configured to be inductively coupled with the conductive member.
a primary device connectable to a power source and having at least two transmitter plates configured to be selectively capacitively coupled with the conductive member and to induce a current flow and generate a magnetic field therein;
a switching means to switch between the first and second connection modes; wherein in the first connection mode, the primary device is connected to the at least two transmitter plates and in the second connection mode the primary device is directly connected) to the conductive member.

Preferably, the reflection coil further comprise a ferrite and/or a non-ferrite reflection material.

As used herein the term “and/or” means “and” or “or”, or both.

As used herein “(s)” following a noun means the plural and/or singular forms of the noun,

The term “comprising” as used in this specification means “consisting at least in part of”. When interpreting statements in this specification which include that term, the features, prefaced by that term in each statement, all need to be present, but other features can also be present. Related terms such as “comprise” and “comprised” are to be interpreted in the same manner.

It is intended that reference to a range of numbers disclosed herein (for example, 1 to 10) also incorporates reference to all rational numbers within that range (for example, 1, 1.1, 2, 3, 3.9, 4, 5, 6, 6.5, 7, 8, 9 and 10) and also any range of rational numbers within that range (for example, 2 to 8, 1.5 to 5.5 and 3.1 to 4.7).

The entire disclosures of all applications, patents and publications, cited above and below, if any, are hereby incorporated by reference.

The disclosed subject matter also provides a method or system which may broadly be said to consist in the parts, elements and features referred to or indicated in this specification, individually or collectively, in any or all combinations of two or more of those parts, elements or features. Where specific integers are mentioned in this specification which have known equivalents in the art to which the invention relates, such known equivalents are deemed to be incorporated in the specification.

Other aspects of the invention may become apparent from the following description which is given by way of example only and with reference to the accompanying drawings.

### DRAWING DESCRIPTION

A number of embodiments of the invention will now be described by way of example with reference to the drawings as follows.

FIG. 1 depicts the block diagram of the system that can transfer power across a metal barrier based on the proposed method.

FIG. 2 depicts the directions of the AC current in the metal barrier and the AC magnetic field upon the barrier.

FIG. 3 depicts an equivalent circuit of the proposed system with a combined CPT-IPT coupler.

FIG. 4 shows a metal barrier with a rectangular cross-section in the 3D coordinate system.

FIG. 5 shows a square sub-bars of the metal barrier

FIG. 6 depicts the 3D geometric graph of the current density vector and the magnetic flux density vector

FIG. 7 is a simulation model of the current CPT-IPT setup in the CST Studio Suite

FIG. 8 shows the current density distribution in the metal barrier,

FIGS. 9a to 9D show the shows the simulated and theoretical contour and vector maps of the magnetic flux density distribution on the xz-cross-section. In (a) the color ramp, in (b) the simulated contour map, in (c) the simulated vector map and in (d) the theoretical contour and vector map of the magnetic flux density distribution on the xz-cross-section are demonstrated.

FIGS. 10a to 10D shows the simulated and theoretical results of the magnetic flux density distribution on the xy-cross-section. In (a) the color ramp, in (b) simulated contour map, in (c) simulated vector map and in (d) the theoretical contour and vector map of the magnetic flux density distribution on the xy-cross-section (the cross-section is 5 mm higher than the metal barrier) are demonstrated.

FIGS. 11A to 11E depict the accurate magnetic flux density magnitude on the xz-cross-section at different height. In (a) the simulated and in (b) the theoretical magnetic flux density magnitude at different height are demonstrated.

FIG. 12 shows a practical prototype of the proposed CPT-IPT combined system to transfer power through a metal barrier wirelessly.

FIG. 13 depicts the simulated, theoretical and the experimental results of the magnetic flux distribution above the metal barrier (the practically measured magnetic flux density upon the metal barrier at different points).

FIG. 14 illustrates the simulation result of the magnetic field distribution (magnetic flux density distribution) with the ferrite core of the receiving coil.

FIG. 15 shows a graph depicting the pick-up power at different locations.

FIG. 16 shows the experimental waveforms of the prototype when the when the coil is installed at the edges of the barrier, while the distance Δz tends to be zero.

FIG. 17 shows the experimental waveforms of the prototype when the coil is installed in the middle region of the barrier, while the distance Δz equals to 20 mm.

### DETAILED DESCRIPTION OF THE DRAWINGS

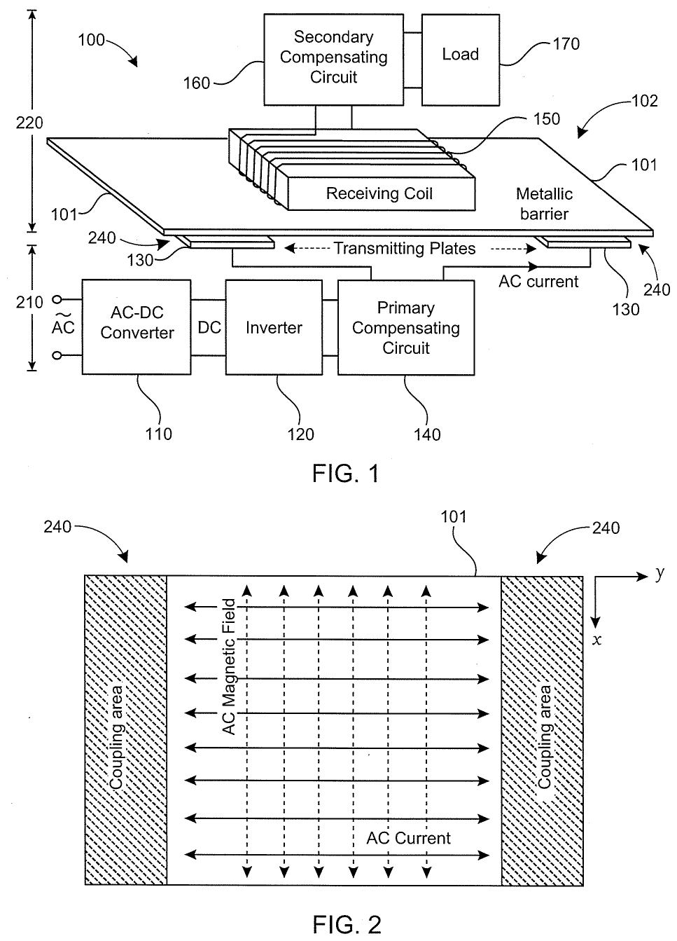

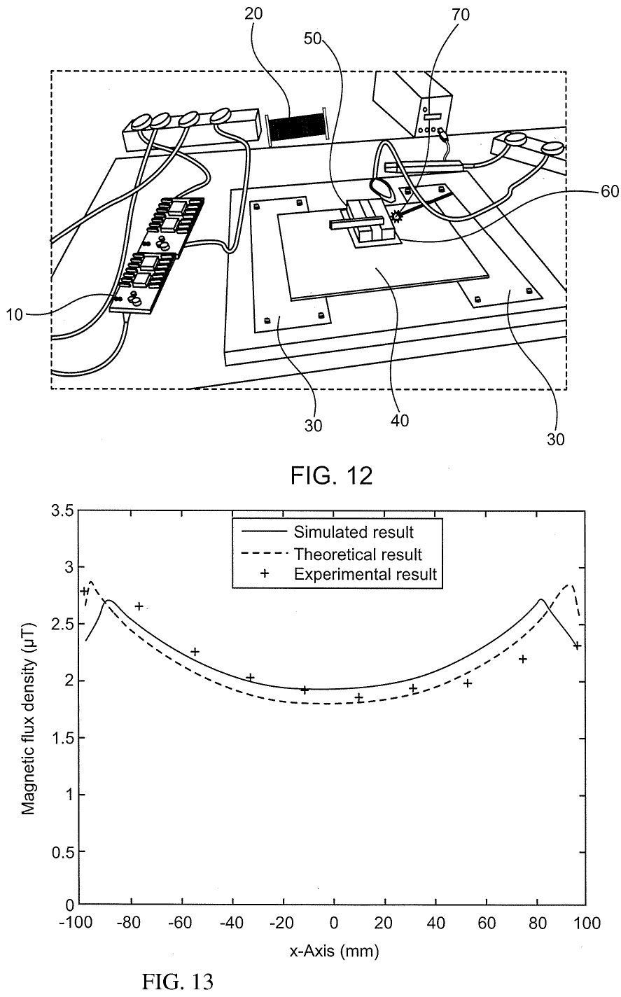

The current invention discloses a novel method and apparatus for wireless power transfer across an electrically conductive member, such as an object which is itself conductive, or which has a conductive layer, or surface by a combined capacitive and inductive coupling topology (100) as shown in FIG. 1 (a similar example is also shown in FIG. 12). The proposed method is described based on the system in the block diagram illustrated in FIG. 1. The metal (101) barrier (electrically conductive layer or an electrically conductive surface) divides the whole system into two sides: the transmitting side (210) and receiving side (220) which are linked by a coupling interface (102). The transmitting (210) side contains an AC-DC converter (110) which can be regarded as providing a DC voltage source. Then the DC voltage is transformed into an AC voltage by the inverter module (120). The metal barrier (101) is capacitively coupled with two primary structures which in this example are in the form of transmitting plates (130) which forms two series capacitors (240).

To counteract the large reactance of the coupling capacitors (240) and enhance the AC current in the circuit, a primary compensating circuit (140) is provided in the transmitting side (210). On the receiving side (220), a receiving coil (150) upon the conductive barrier (101) is connected up to the secondary compensating circuit (160) and the load (170) successively. The secondary compensating network (160) is on or near resonance with the receiving coil so as to increase power transfer capability of the system. In another embodiment, the present wireless power transfer apparatus (100) is configured to being operable in a first and a second connection mode (not shown in FIG. 1) and comprises a switching means (also not shown in FIG. 1) to switch between the first and second connection modes wherein in the first connection mode, the primary device (210) is connected to the at least two transmitter plates (130) and in the second connection mode the primary device (310) is directly connected to the conductive layer.

### Operating Principle

As introduced above, the inverter (120) transforms the DC voltage into a high frequency AC voltage, which is connected up to the compensating circuit (140), so that an alternating voltage can be stimulated between two transmitting plates (130), Then an AC current flows along the metal barrier (101) between two coupling areas corresponding to the locations of plates 130 because the metal barrier (101) is coupled with the transmitting plates (130). According to Ampere's Law, an alternating magnetic field can be stimulated around the metal barrier (101). Directions of the magnetic field upon the barrier and the AC current in the barrier are shown in FIG. 2, which are orthogonal to each other. The combination of the transmitting circuit (210) and the metal barrier (101) forms a magnetic field generator which has a similar function to conventional IPT transmitting circuits. Instead of the multiple-turn coil in typical IPT systems, the metal barrier in the proposed system is more like a primary single-turn coil, similar with a current transformer (CT). In the receiving side (220), the pick-up coil (150) is laid nearby the metal barrier and the magnetic field transfers through the coil, so that an EMF can be excited on the coil based on Faraday's Law. Finally, with a proper compensating module (160) in the receiving circuit (150), a certain level of power can be transferred to the load (170).

Instead of choosing two transmitting plates (130) in the primary side (210), a transmitting coil will result in an uncontrollable eddy current in the barrier, which might can cause high losses and safety concerns. A capacitive interface is chosen in the primary side because the stimulated AC current in the metal barrier can be controlled by regulating the inverter. With this current, a magnetic field is excited and distributed around the metal barrier, however, the electric-field in the secondary side is almost shielded by the metal barrier. So an inductive coupling interface in the secondary side is more suitable than a capacitive one to pick up power from an alternative magnetic field.

In the coupling interface (102), the transmitting plates and metal barrier form a capacitive coupler, while the barrier and receiving coil form an inductive coupler. Therefore, the combination of them can be regarded as a combined capacitive-inductive (CPT-IPT) coupler.

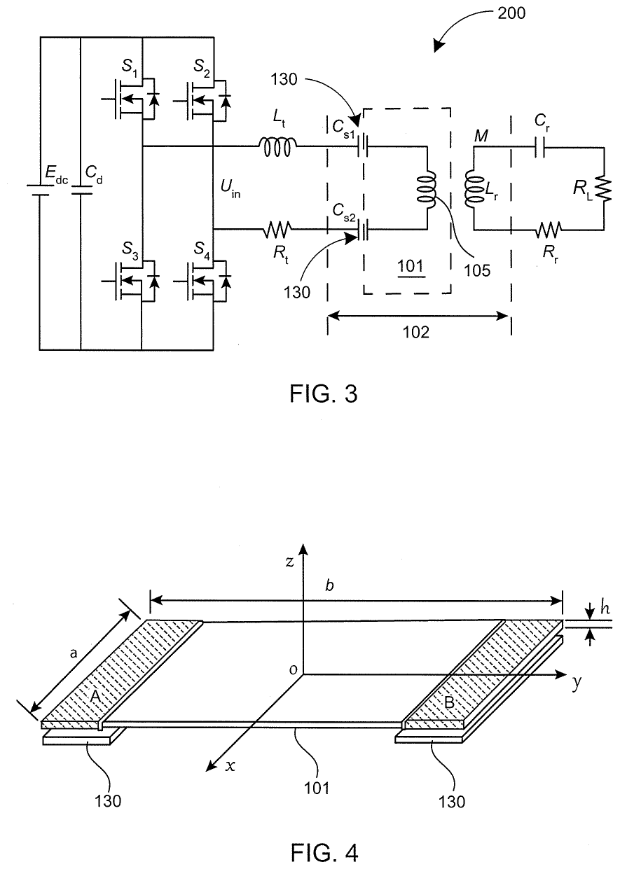

Based on the operating principle introduced above, an equivalent circuit (200) with specific sub-circuits is illustrated in FIG. 3 to make the system more comprehensible. The DC voltage source E dc in FIG. 3 represents the output of the AC-DC converter (110) in FIG. 1. An H-bridge inverter with four switches S1-4 is adopted, whose output voltage is Uᵢₙ. The primary compensating circuit is formed by an inductor Lₜ connected to the coupling capacitors ₛ₁ and Cₛ₂ in series coupling capacitors Cₛ₁ and Cₛ₂ correspond to capacitors (240) in FIG. 1. The inductor 105 represents the primary single-turn coil. In the receiving side, Lᵣ is the receiving coil (referenced (150) in FIG. 1) and Cr is a series compensating capacitor corresponding to the compensation network or circuit (160) of FIG. 1. R_{L} is the resistive load of the system corresponding to load (170) of FIG. 1. Rₜ and Rᵣ indicate the internal resistances of the transmitting and receiving loops, respectively.

. The left side of each two capacitors Cₛ₁ and Cₛ₂ represent the two transmitting plates (130). The right side of two capacitors and the primary coil of the inductive coupling interface, which are blocked by the dashed box, correspond to the metal barrier (101). Because the metal barrier can be regarded as the single-turn wire, so that the primary self-inductance of the inductive coupling interface (105) is very small and can be negligible. The secondary coil of the equivalent transformer refers to the receiving coil (150) upon the metal barrier. The combination of above objects represents a CPT-IPT combined coupling interface (102).

### Analysis of the Combined Coupling

In the proposed system in FIG. 1, the power transfer characteristics and capability depend on the current in the barrier and the magnetic field around it. Because of the high operating frequency, the skin effect in the conductor cannot be neglected and should be taken into account. Therefore, the current density distribution and the magnetic flux density distribution are analyzed in this section.

### A. Current Density Distribution Analysis in the Metal Barrier

Because of the skin effect under the high operating frequency, the current density doesn't distribute evenly in the conductive member, instead, there is a tendency of the current to be larger near the surface of the conductor, and decreases with greater depths in the conductor. In this section, a conductor with a rectangular cross-section and small thickness is adopted as a metal barrier in the analysis, which is similar with the metal back cover or rear housing of some consumer electronic devices such as mobile telephones or tablet computers. The width, length and the thickness of the barrier are defined as a, b and h, respectively.

Because the areas A and B on the barrier is coupled with the transmitting plates, the voltage potentials of these two areas are different to each other and they can be regarded as the current input port that can inject current into the metal barrier. Because of the serious skin effect and the small thickness of the metal barrier, it is reasonable to assume that the most of current flows along the y-direction between the area A and B. So the problem can be simplified as a mathematical calculation of the current density distribution in a conductor with a rectangular cross-section. According to Antonini et al., (G. Antonini, A. Orlandi, and C. R. Paul, “Internal impedance of conductors of rectangular cross-section,” IEEE Trans. Microw. Theory Tech., vol. 47, no. 7, pp. 979-985, 1999), the continuous current density distribution function on the xz-cross-section can be presented as:

$$J x , z = - \frac{i {ωμ}_{Al} {σ}_{Al}}{2 π} \cdot {\int }_{s} J ξ , ζ ln \sqrt{x - {ξ}^{2} + z - {ζ}^{2}} d ξ d ζ + {J}_{i n} \qquad ( 1 )$$

where μAl and σAl represent the permeability and conductivity of the metal barrier, respectively. S is the cross-section of the conductor. Jᵢₙ is the average current density on the boundary. The analytical solution of this integral equation is difficult to be found out, however, presenting a numerical solution is easier. To get the numerical solution, the cross-section of the conductor is divided into N rectangular sub-bars with square cross-sections as shown in FIG. 5.

The cross-section of the m-th sub-bar is defined as ΔSₘ, and the area of all the sub cross-sections are ΔS. The coordinate of the m-th sub-bar is (xₘ, zₘ), while the current flowing in it is Jm. Then the expression of the current Jₘ can be derived as follow via the discretization of the continuous expression Equation (1).

$${J}_{m} = - \frac{i {ωμ}_{Al} {σ}_{Al}}{2 π} \cdot Δ S \cdot {\sum }_{n = 1}^{N} {J}_{n} {Δ}_{m n} + {J}_{in} \qquad ( 2 )$$

where m∈[1, N] and

$${Δ}_{m n} = \frac{{\int }_{Δ {S}_{m}} {\int }_{Δ {S}_{n}} ln \sqrt{{x}_{m} - {x}_{n}^{2} + {z}_{m} - {z}_{n}^{2}} d {x}_{m} {dz}_{m} d {x}_{n} {dz}_{n}}{Δ {S}^{2}} \qquad ( 3 )$$

By transforming the summation symbol into a matrix form, Eq. (2) can be rewritten as:

$${[ \begin{matrix}{J}_{1 \vert} \\ {J}_{2} \\ ⋮ \\ {J}_{N}\end{matrix} ]}_{J} = {\underbrace{- \frac{i {ωμ}_{Al} {σ}_{Al}}{2 π} \cdot Δ S}}_{- i ψ} \cdot {\underbrace{[ \begin{matrix}{Δ}_{11} & {Δ}_{12} & … & {Δ}_{1 N} \\ {Δ}_{21} & {Δ}_{22} & … & {Δ}_{2 N} \\ ⋮ & ⋮ & ⋱ & ⋮ \\ {Δ}_{N 1} & {Δ}_{N 2} & … & {Δ}_{N N}\end{matrix} ]}}_{A} {[ \begin{matrix}{J}_{1} \\ {J}_{2} \\ ⋮ \\ {J}_{N}\end{matrix} ]}_{J} + {J}_{in} \qquad ( 4 )$$

$$⇔ J = - i ψ AJ + {J}_{in} \qquad ( 5 )$$

Since J represents the current density which is a complex vector, J can be given as:

J=Jᵣₑₐₗ+iJ_{imag} (6)

where Jᵣₑₐₗ and J_{imag} represent the vectors of the real part and the imagery part of the vector J. Then the matrix equation can be rewritten as:

Jᵣₑₐₗ−ψAJ_{imag}+iJ_{imag}+ψAJᵣₑₐₗ=Jᵢₙ (7)

Define Jᵣₑₐₗ and J_{imag} as:

$$\{ \begin{matrix}{J}_{real} = [ \begin{matrix}{J}_{real , 1} , & {J}_{real , 2} , & … , & {{J}_{real , N} ]}^{T}\end{matrix} \\ {J}_{imag} = [ \begin{matrix}{J}_{imag , 1} , & {J}_{imag , 2} , & … , & {{J}_{imag , N} ]}^{T}\end{matrix}\end{matrix} . \qquad ( 8 )$$

Substituting Eq. (8) into Eq. (7), then the matrix equation Eq. (7) can be expanded as:

$$[ \begin{matrix}\begin{matrix}{J}_{real , 1} \\ ⋮\end{matrix} \\ \frac{{J}_{real , N}}{{J}_{imag , 1}} \\ ⋮ \\ {J}_{imag , N}\end{matrix} ] = {[ \begin{matrix}\begin{matrix}1 & & \\ & ⋱ & \\ & & 1\end{matrix} \\ \overline{\begin{matrix}{ψΔ}_{11} & … & {ψΔ}_{1 N} \\ ⋮ & ⋱ & ⋮ \\ {ψΔ}_{N1} & … & {ψΔ}_{NN}\end{matrix}}\end{matrix} \begin{matrix}\begin{matrix}- {ψΔ}_{11} & … & - {ψΔ}_{1 N} \\ ⋮ & ⋱ & ⋮ \\ - {ψΔ}_{N1} & … & - {ψΔ}_{NN}\end{matrix} \\ \overline{\begin{matrix}1 & & \\ & ⋱ & \\ & & 1\end{matrix}}\end{matrix} ]}^{- 1} \cdot [ \begin{matrix}\begin{matrix}{J}_{in} \\ ⋮\end{matrix} \\ \frac{{J}_{in}}{0} \\ ⋮ \\ 0\end{matrix} ] \qquad ( 9 )$$

Finally, the magnitude of the current density on each sub-bar can be presented as:

|Jₘ|=\sqrt{J_{real,m}²+J_{imag,m}²} (10)

B. Magnetic Flux Density Distribution Analysis around the Barrier

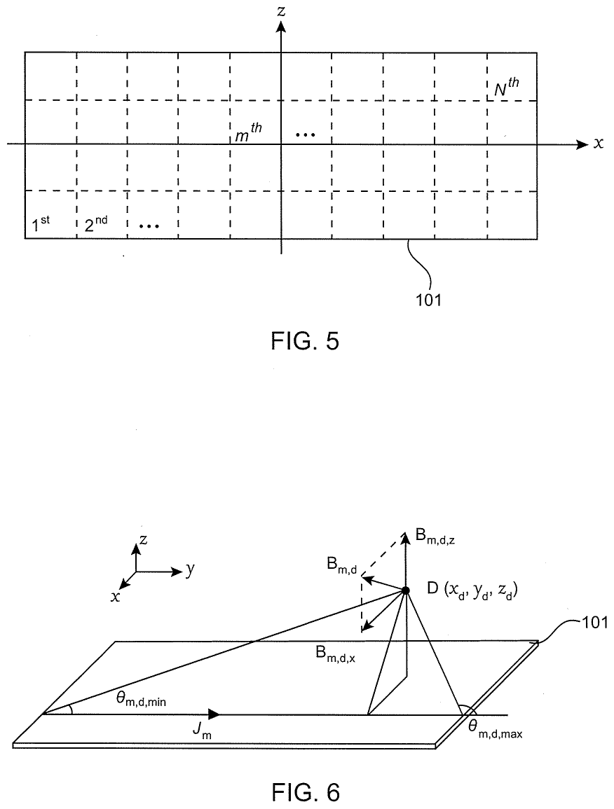

According to the Biot-Savart Law, the magnetic flux density near the metal plate can be calculated. The 3D geometric graph of the current density vector and the magnetic flux density vector is shown in FIG. 6. The magnetic flux density vector at an arbitrary point D with the coordinate of (x_{d}, y_{d}, z_{d}) excited by the current on the m-th sub-bar is:

$${B}_{m , d} {x}_{d} , {y}_{d} , {z}_{d} = \frac{{μ}_{air} \vert {J}_{m} \vert}{4 π {d}_{m , d}} cos {θ}_{m , d , min} - cos {θ}_{m , d , max} \cdot {e}_{B} \qquad ( 11 )$$

In eq. (11),

$$\{ \begin{matrix}{d}_{m , d} = \sqrt{{x}_{d} - {x}_{m}^{2} + {z}_{d} - {z}_{m}^{2}} \\ {e}_{B} = \frac{{z}_{d} - {z}_{m}}{{d}_{m , d}} \cdot {e}_{x} + \frac{{x}_{m} - {x}_{d}}{{d}_{m , d}} \cdot {e}_{z}\end{matrix} \qquad ( 12 )$$

and

$$\{ \begin{matrix}cos {θ}_{m , d , max} = \frac{{y}_{d} - b / 2}{\sqrt{{x}_{d} - {x}_{m}^{2} + {y}_{d} - b / {2}^{2} + {z}_{d} - {z}_{m}^{2}}} \\ cos {θ}_{m , d , min} = \frac{{y}_{d} + b / 2}{\sqrt{{x}_{d} - {x}_{m}^{2} + {y}_{d} + b / {2}^{2} + {z}_{d} - {z}_{m}^{2}}}\end{matrix} \qquad ( 13 )$$

where, μₐᵢᵣ is the permeability of air, eₓ and e_{z} represent the unit vectors on the x- and z-directions, respectively. Besides, dm,d indicates the Euclidean distance between the point (x_{d}, y_{d}, z_{d}) and the m-th sub-bar. The coordinate of the m-th sub-bar is (xₘ, zₘ). The 3D geometric graph of the current density vector and the magnetic flux density vector.

Then the horizontal and vertical components of the vector B_{m,d}(x_{d}, y_{d}, z_{d}) can be presented as:

$$\{ \begin{matrix}\vert {B}_{m , d , x} {x}_{d} , {y}_{d} , {z}_{d} \vert = \frac{{z}_{d} - {z}_{m}}{{d}_{m , d}} \cdot \vert {B}_{m , d} {x}_{d} , {y}_{d} , {z}_{d} \vert \\ \vert {B}_{m , d , z} {x}_{d} , {y}_{d} , {z}_{d} \vert = \frac{{x}_{m} - {x}_{d}}{{d}_{m , d}} \cdot \vert {B}_{m , d} {x}_{d} , {y}_{d} , {z}_{d} \vert\end{matrix} \qquad ( 14 )$$

Therefore, the total magnetic flux density vector at the point of (x_{d}, y_{d}, z_{d}) stimulated by the current in all sub-bars can be given as:

$${B}_{d} {x}_{d} , {y}_{d} , {z}_{d} = {\sum }_{m = 1}^{N} \vert {B}_{m , d , x} {x}_{d} , {y}_{d} , {z}_{d} \vert \cdot {e}_{x} + {\sum }_{m = 1}^{N} \vert {B}_{m , d , z} {x}_{d} , {y}_{d} , {z}_{d} \vert \cdot {e}_{z} \qquad ( 15 )$$

### Simulation Study

To verify the theoretical analysis and solutions above, a 3D simulation model is established using CST package, which is an electromagnetic field simulation software, and the simulation results are compared with the theoretical results according to the analysis in the analysis of the combined coupling section presented above.

### Current Density Distribution Analysis in the Metal Barrier

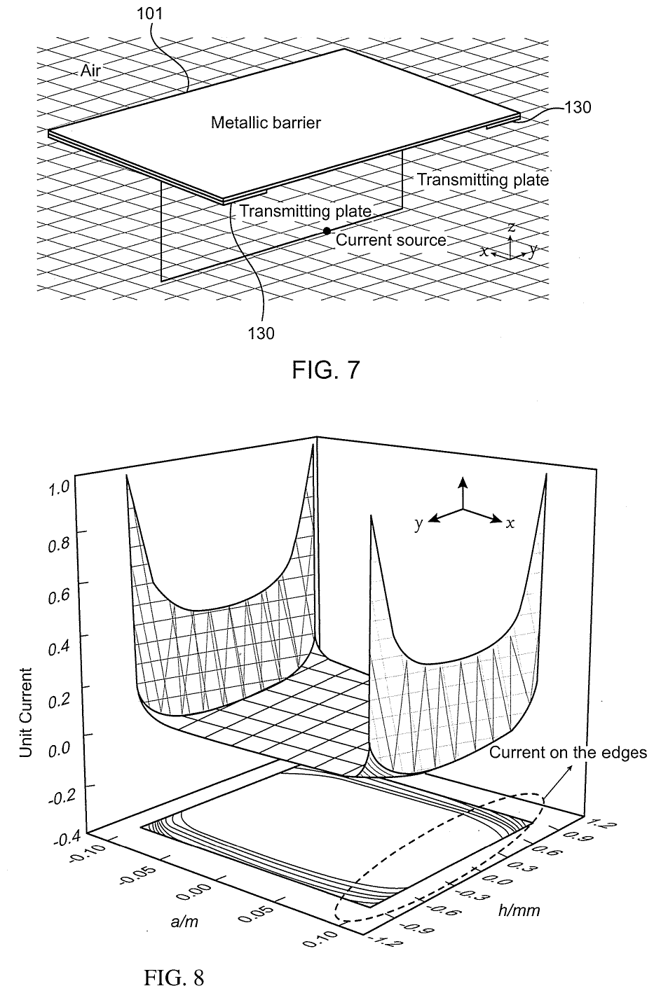

The simulation model is shown in FIG. 7. In the simulation model, the aluminum material is adopted for the metal barrier and transmitting plates, whose conductivity is 3.56×10⁷ S/m and permeability is 1.26×10⁻⁶ H/m. A current source is connected up to the middle point of the transmitting plates. The preset parameters of the model is listed in Table I.

TABLE I
THE PRESET PARAMETERS OF THE SIMULATION
MODEL IN CST PACKAGE

| Parameters | Values | Parameters | Values |
|---|---|---|---|
| Metal | 295 × 195 × 2 (mm) | Transmitting | 195 × 50 × 2 (mm) |
| barrier size | | plate size | |
| Metal material | Aluminum | Background | Air |
| Injecting | 1 (A) | Frequency | 479 (kHz) |
| current | | | |
| Accuracy | 10⁻⁶ | | |

### Calculation of Current Density

Based on the calculation steps in Section current distribution analysis in the metal barrier above, the current density distribution inside of a conductor with a rectangular cross-section can be shown as Eqn. (10), Substituting the metal barrier size into the equation, the unit current distribution of the metal barrier is illustrated in FIG. 8.

In FIG. 8, it is obvious that the unit current on the margin of the cross-section is higher than that in the middle region, which means most of current flows along the surface of the metal barrier. Especially, the current on the edges varies from 0.35 to 1.0, which is much higher than the current in other region.

### Comparison between the Theoretical and Simulated Results

Beside the simulation result of the magnetic flux distribution, the theoretical magnetic field distribution is also calculated based on the analysis of the combined coupling (as discussed above) with the same preset parameters in Table I.

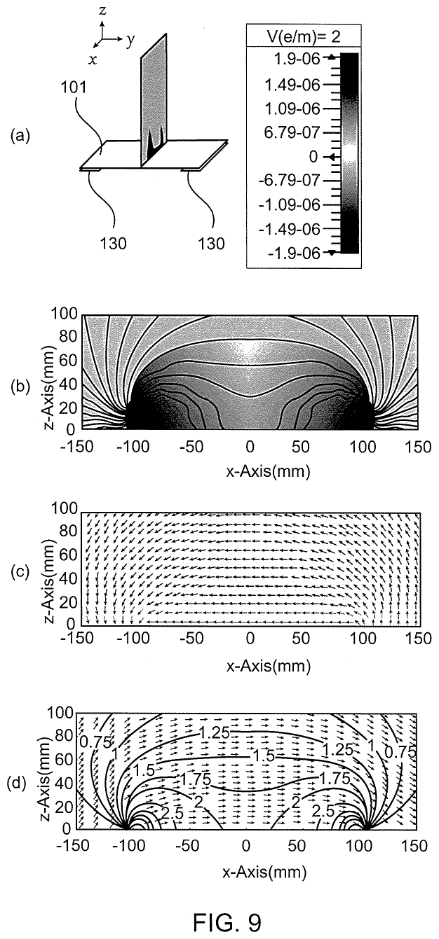

FIG. 9 shows the simulated and theoretical contour and vector maps of the magnetic flux density distribution on the xz- cross-section. FIG. 9(a) shows the color ramp of the simulation result. From FIG. 9(b), it shows that the magnetic flux density near the edge of the metal barrier is stronger than that in the middle region. In FIG. 9(c), we can find that the horizontal magnetic field component is the main part, especially in the middle region. The component on the z-direction tends to be larger near the edge of the barrier. The theoretical contour and vector maps calculated based on Eq. (15) are shown in FIG. 9(d), which gives similar results compared to the simulated results.

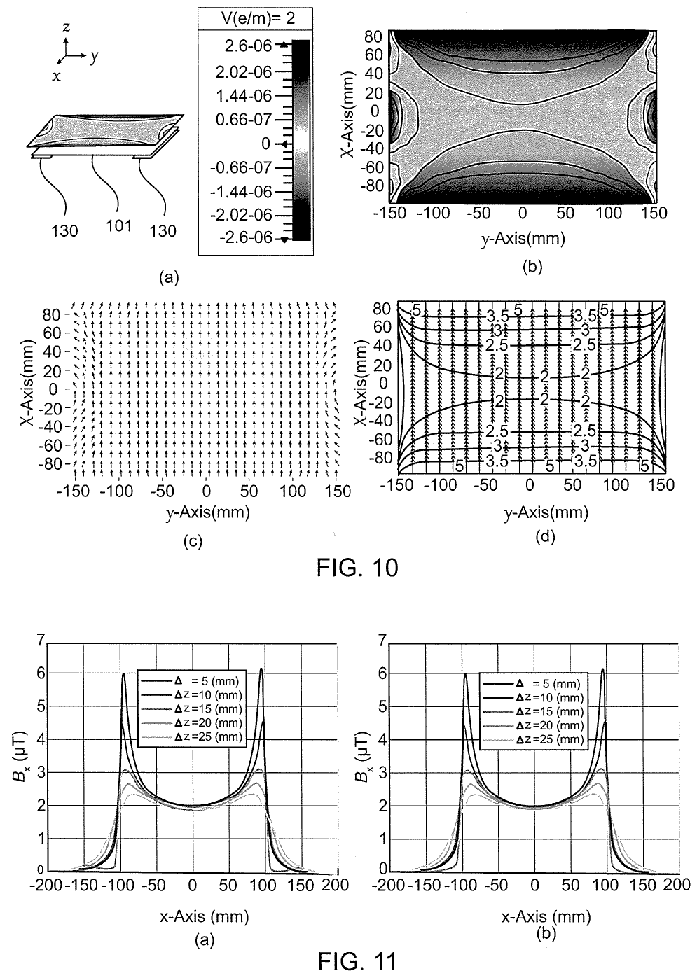

FIG. 10 shows the simulated and theoretical results of the magnetic flux density distribution on the xy-cross-section. Similar with FIG. 9(b), FIG. 10(b) shows that the magnetic flux density near the edge of the metal barrier is stronger than that in the middle region. In FIG. 10(c), it is obvious that the component of the magnetic field vector on the y-direction is negligible. The theoretical contour and vector maps are shown in FIG. 10(d), which are also similar with the simulated results.

FIG. 11 illustrated the accurate magnetic flux density magnitude on the xz-cross-section at different height. In both of FIG. 11(a) and (b), Δz represents the distance between the measured point and the metal barrier, It shows that the magnetic flux density achieves the maximum at two edges. With the increasing Δz, the magnetic flux density magnitude tends to be smaller seriously at the edge, while the magnitude decreases slightly in the middle region.

### Experimental Study

To verify the theoretical analysis and simulation results practically, a prototype has been built and two experiments have been conducted. The first experiment is designed to detect the magnetic flux density distribution upon the metal barrier and compared with the theoretical and simulated distribution. The second one is conducted to confirm the feasibility of power transmission in this method.

### Experimental Setup

The prototype for the experiment has been built as shown in FIG. 12. The metal barrier (40) is a thin rectangular aluminum plate with the size of 295×195×2 mm. The transmitting plates (30) are also made of aluminum material with the size of 295×100×2 mm, which is larger than the theoretical and simulation preset. But their effective coupling regions are all 195×50 mm. So the larger practical size of the transmitting (30) plates doesn't affect the power transfer characteristics. We adopted the larger plates in the experimental setup because a larger size is benefit to fix the transmitting plates (30) on the wood base. The metal barrier plate (40) and the transmitting plates (30) are isolated by a piece of Polyethylene Terephthalate (PET) film. In the transmitting side, a full-bridge inverter (10) with four Silicon Carbide (SiC) MOSFETs (C2M0080120D) is used to generate a high frequency voltage. The high reactance of the capacitive coupling interface is compensated by an air core inductor (20) with the Litz-wire windings. For the first experiment, a 35-turn air core open circuit coil with the size of 155×45×10 mm is adopted as the detecting coil. In the second experiment, due to the small self-inductance of the metal barrier (40), the mutual coupling between the barrier and the receiving coil is weak, which means the flux density across the receiving coil (50) would be low. So a ferrite core is used in the pick-up coil of the receiving part to enhance the magnetic flux across the coil. The type of ferrite core is TDK-I-N87 (MnZn material) and with a relative permeability of 2000 (±25%) and a size of 95×56×16 mm. The receiving coil (50) is also fully tuned by mica capacitors (60), which are suitable for high frequency applications. The circuit parameters of the prototype are listed in Table II.

TABLE II
THE PARAMETERS OF THE PRACTICAL PROTOTYPE

| Parameters | Values | | Parameters | Values | |
|---|---|---|---|---|---|
| Lₜ | 114 | (μH) | Cₛ₁/Cₛ₂ | 970 | (pF) |
| Lᵣ | 72.1-95.2 | (μH) | Cᵣ | 1.16-1.53 | (nF) |
| R_{L} | 7.6 | (Ω) | Frequency | 479 | (kHz) |
| Iₜ | 2 | (A) | E_{dc} | 20 | (V) |

### Magnetic Flux Density Measurement

Before the output power measurement, the magnetic flux density Bₓ upon the metal barrier is measured to verify the magnetic flux density distribution calculation and simulation above. It is hard to measure Bₓ at each point directly, so the measuring method here is setting an open circuit detecting coil inside of the magnetic field and measure the open circuit voltage on the output port of the detecting coil. Then the average magnetic flux density across the detecting coil can be calculated from:

$$\overline{B} = \frac{{U}_{open}}{ω {S}_{coil} {N}_{coil}} \qquad ( 16 )$$

where S_{coil} is the cross-section of the detecting coil, Uₒₚₑₙ is the EMF on the coil and N_{coil} is the turn number of the coil. The simulated, theoretical and the experimental results of the magnetic flux distribution above the metal barrier are illustrated in FIG. 13, respectively. In this figure, the practical value of the magnetic flux density is not strictly symmetrical, however, the coupling structure is symmetric and the magnetic field should distribute symmetrically. The reason is there are several factors might affect the symmetrical distribution of the magnetic field in the experimental setup: the transmitting plates are not strictly parallel with the metal barrier and the external electromagnetic field, etc. In summary, the experimental results matches the theoretical and simulation results very well.

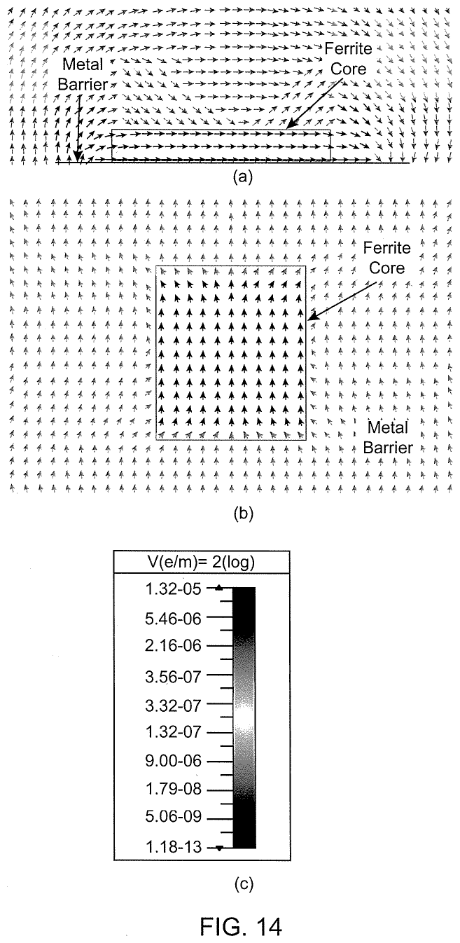

After the ferrite core is added in the receiving coil, the magnetic field distribution will change because of the effect of the ferrite core on the magnetic field. The simulation result of the magnetic field distribution are shown in FIG. 14. In FIG. 14, the magnetic field is attracted by the ferrite core, which result in a higher magnetic flux density across it and a higher EMF in the receiving coil. The output power of the system with the ferrite core in the secondary side is measured in the next part.

When the conductive layer is inserted between two coils of an IPT system the eddy currents in the conductive layer are dependent on both the operating frequency and the position of the receiving coil. As such, the distance between the conductive surface and the receiving coil effects the eddy currents. For example, a larger distance provides smaller eddy currents on the conductive surface and vice versa. Therefore, by changing the coupling configuration the eddy currents can be varied as well.

### Output Power Measurement

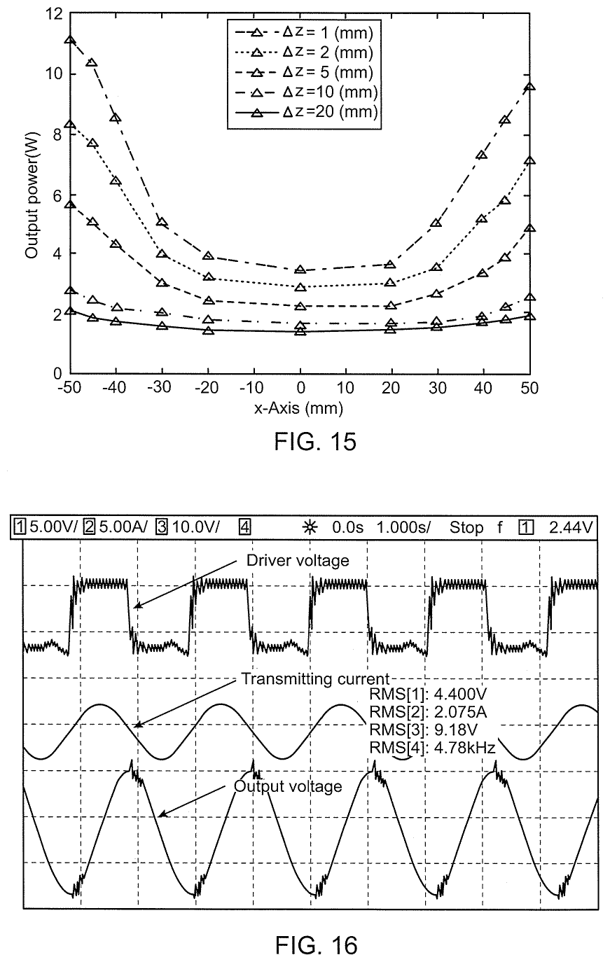

Based on the prototype in FIG. 12, the output power is also measured with the variation of the receiving coil location. As for the receiving coil, with the different relative location to the metal barrier, the inductance of the coil varies in a certain range because of the effect of the barrier on the coil. In this prototype, the inductance Lᵣ varies from 72.1-95.2 pH when the coil moves from the edges to the middle region. Therefore, the compensating capacitor Cᵣ is also modulated from 1.16-1.53 nF to ensure that the receiving circuit operates on the fully tuned condition. The location of the receiving coil changes on the x- and z-direction when y=0, while the receiving coil moves between two edges of the metal barrier and the distance between the coil and the barrier varies from 0-20 mm. The measured results are listed in Table III. According to the data in Table III, the pick-up power at different locations are illustrated in FIG. 15.

TABLE III
THE EXPERIMENTAL RESULTS WITH RECEIVING
COIL MOVES ALONG THE X- AND Z-DIRECTION
(UNIT OF POWER: W)

| | Δz (mm) | | | | |
|---|---|---|---|---|---|
| x (mm) | 1 | 2 | 5 | 10 | 20 |
| −50 | 11.09 | 8.30 | 5.64 | 2.81 | 2.15 |
| −45 | 10.32 | 7.66 | 5.04 | 2.44 | 1.84 |
| −40 | 8.55 | 6.42 | 4.30 | 2.20 | 1.73 |
| −30 | 5.01 | 3.96 | 3.00 | 2.01 | 1.60 |
| −20 | 3.87 | 3.19 | 2.41 | 1.76 | 1.44 |
| 0 | 3.41 | 2.84 | 2.24 | 1.62 | 1.38 |
| 20 | 3.61 | 2.97 | 2.28 | 1.64 | 1.42 |
| 30 | 4.98 | 3.44 | 2.60 | 1.71 | 1.53 |
| 40 | 7.24 | 5.12 | 3.31 | 1.89 | 1.68 |
| 45 | 8.39 | 5.72 | 3.76 | 2.16 | 1.74 |
| 50 | 9.45 | 7.01 | 4.83 | 2.51 | 1.87 |

FIG. 15 shows the output power on the load at different locations. It is obvious that more power can be picked up near the edges of the metal barrier and less power in the middle region, which is similar to the magnetic flux density distribution analyzed above. Moreover, with the increasing distance Δz between the receiving coil and the metal barrier, the output power also decreases, especially near the edges. When Δz equals to 1 mm, up to 11.09 W power was picked up at the edges and 3.41 W at the middle point, which decreased about 69.25 9/0. When Δz increased to 20 mm, the maximum picked up power at the edges decreased to 2.15 W, while the power received in the middle region dropped to 1.38 W. The output power only decreased 35.81%, which is smaller than that in the condition when Δz is 1 mm. It means that with a smaller distance between the coil and the barrier, the pick-up power tends to be more sensitive to the location on x-direction.

Moreover, the output power near the edges of the metal barrier is more sensitive to the distance Δz than that in the middle region. In FIG. 15, with the increase of the distance Δz from 1-20 mm at the edges, the pick-up power dropped from 11,09 W to 2.15 W, which decreased 80.61%. However, when the receiving coil was in the middle region, the pick-up power only decreased 59.53% from 3.41 W to 1.38 W when the distance Δz raised. Besides, the efficiency of the system when the output power achieves the peak (11.09 W) is 41.6%.

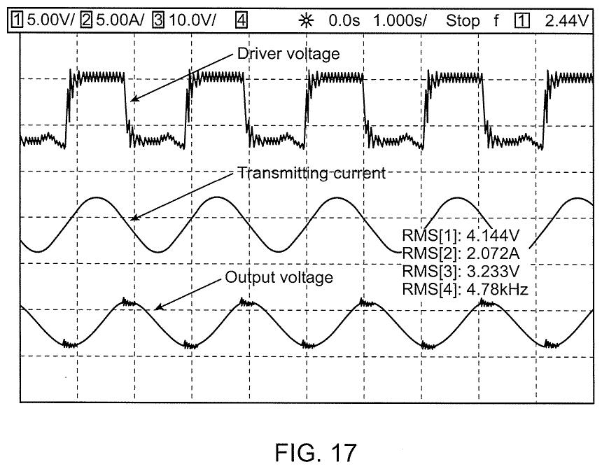

Consequently, the pickup power is sensitive to the coil location when the coil is installed at the edges of the barrier. However, in this case, the maximal power can be received while the distance Δz tends to be zero. The experimental waveforms under this condition is illustrated in FIG. 16. Moreover, the output power level decreases to a lower level compared to the former condition when the coil is set in the middle region of the barrier. But the pick-up power is more stable. The practical waveforms under this condition is shown in FIG. 17.

The experimental results demonstrate that the maximum output power of 11.09 W is transferred across the metal barrier. Such a power level is sufficient to meet the power requirement of portable electronic devices such as cell phones with metallic back covers, and it can also be used for slow charging of tablet PCs, and digital cameras. The power transfer capability of the proposed wireless power transfer method can be further increased for other higher power applications such as laptops and logistics robots. The system can be potentially used for special applications such as transferring power across metal hulls of a boat for driving fish founders.

A wireless power transfer method to transfer power across a metal barrier by a capacitive and inductive combined coupling was proposed. The current density distribution in the metal barrier was analyzed by taking the skin effect into consideration. Then the magnetic field distribution around the metal surfaces was determined based on the current density distribution. A simulation model in CST package and a practical wireless power transfer system with combined IPT-CPT coupling were constructed to verify the theoretical analysis. The simulated result and the practical measurement of magnetic flux density were compared with the theoretical calculation, which gave consistent results. The results showed that the magnetic flux density near the edges are higher than that in the middle, although the flux density is more sensitive to the variation of the distance and positioning of the receiving coil around the edges. Finally, it has demonstrated that more than 11 W of power can be transferred across an aluminum plate with a thickness of 2 mm when the power pickup is placed at one edge of the plate. The results from the analysis above demonstrate the feasibility of transferring power across metal barriers, which can be potentially used to design various wireless power supplies for portable electronic devices with metal covers which is lacking in existing WPT systems.

Throughout the description like reference numerals will be used to refer to like features in different embodiments.

Unless the context clearly requires otherwise, throughout the description, the words “comprise”, “comprising”, and the like, are to be construed in an inclusive sense as opposed to an exclusive or exhaustive sense, that is to say, in the sense of “including, but not limited to”.

Although this invention has been described by way of example and with reference to possible embodiments thereof, it is to be understood that modifications or improvements may be made thereto without departing from the scope of the invention. The invention may also be said broadly to consist in the parts, elements and features referred to or indicated in the specification of the application, individually or collectively, in any or all combinations of two or more of said parts, elements or features. Furthermore, where reference has been made to specific components or integers of the invention having known equivalents, then such equivalents are herein incorporated as if individually set forth.

Any discussion of the prior art throughout the specification should in no way be considered as an admission that such prior art is widely known or forms part of common general knowledge in the field.

1. A wireless power transfer apparatus for wirelessly transferring power, the apparatus comprising:
a conductive member;
a primary device; and
a secondary device, wherein
the primary device and the secondary device are separated by the conductive member,
the wireless power transfer apparatus is for wirelessly transferring power across the electrically conductive member,
the primary device is connectable to a power source, the primary device having at least two transmitter plates configured to be capacitively coupled with the conductive member to induce a current flow and generate a magnetic field in the conductive member, and
the secondary device connectable to a load and provided with a receiving coil configured to be inductively coupled with the conductive member.

2. The wireless power transfer apparatus as claimed in claim 1 wherein a frequency of the power source is chosen such that a magnetic flux density near edges of the conductive member is higher than that in middle region of the conductive member.

3. The wireless power transfer apparatus as claimed in claim 1 wherein the two transmitter plates are located across distal ends of the conductive member and form capacitors in series arrangement with the conductive member.

4. The wireless power transfer apparatus as claimed in claim 1 wherein the primary device further comprises a primary compensation circuit to counteract a reactance of the transmitter plates.

5. The wireless power transfer apparatus as claimed in claim 1 wherein the conductive member is a rectangular prism having dimensions 295 mm×195 mm×2 mm.

6. The wireless power transfer apparatus as claimed in claim 1 wherein the secondary device further comprises a secondary compensation circuit connected to the receiving coil and the load.

7. The wireless power transfer apparatus as claimed in claim 1 wherein the secondary compensation circuit is at or near resonance with the receiving coil.

8. The wireless power transfer apparatus as claimed in claim 1 wherein the primary device further comprises a regulator configured to adjust an operating frequency of the wireless power transfer apparatus.

9. The wireless power transfer apparatus as claimed in claim 8 wherein the regulator comprises a rectifier and an inverter and a fully tuned mica capacitor.

10. The wireless power transfer apparatus as claimed in claim 8 wherein the regulator comprises an AC-AC converter.

11. The wireless power transfer apparatus as claimed in claim 1 wherein the receiving coil comprises a reflection coil positioned at a side of the receiving coil opposite the conductor member.

12. The wireless power transfer apparatus as claimed in claim 1 wherein the reflection coil further comprises a ferrite and/or a non-ferrite reflection material.

13. The wireless power transfer apparatus as claimed in claim 1 wherein the receiving coil is positioned relative to the conductive member such that the eddy currents in the conductive member are substantially smaller.

14. The wireless power transfer apparatus as claimed in claim 1 wherein the primary device is connected directly to the conductive member.

15. The wireless power transfer apparatus as claimed in claim 1 wherein the conductive member comprises a conductive layer or a conductive surface.

16. A primary device for wirelessly transferring power across an electrically conductive member, the primary device connectable to a power source and comprising:
at least two transmitter plates configured to be capacitively coupled with the conductive member to induce a current flow and generate a magnetic field in the conductive member.

17. The primary device as claimed in claim 16 wherein the primary device is separable via the conducting member to a secondary device connected to a load and provided with a receiving coil and the secondary device being inductively coupled with the conductive member.

18-24. (canceled)

25. A method for wirelessly transferring power across an electrically conductive barrier, the method comprising:
capacitively coupling a power source with the conductive barrier to induce a current flow and generate a magnetic field in the conductive barrier;
inductively coupling a coil with the conductive member; and
wherein the power source and the coil are separated by the conductive barrier.

26. The method of claim 25, wherein the electrically conductive barrier is an equivalent circuit component to a primary single-turn coil.

27. The method of claim 25, wherein the electrically conductive barrier is a single flat metal plate.
